(19) United States
(12) Patent Application Publication
(10) Pub. No.: US 2016/0278221 A1
(43) Pub. Date: Sep. 22, 2016

(54) DISPLAY DEVICE INCLUDING ELASTIC MEMBER

(71) Applicant: CANON KABUSHIKI KAISHA, Tokyo (JP)

(72) Inventor: Masashi Morishita, Isehara-shi (JP)

(21) Appl. No.: 15/065,108

(22) Filed: Mar. 9, 2016

(30) Foreign Application Priority Data
Mar. 17, 2015 (JP) 2015-054062

(51) Int. Cl. H05K 5/02; H05K 5/00

(52) U.S. Cl. CPC H05K 5/02; H05K 5/0017

(57) ABSTRACT

A display device according to the present invention includes a liquid crystal panel having a display area on which an image is displayed, and a peripheral edge area around the display area, a frame disposed in back of the liquid crystal panel, and first and second elastic members disposed at positions corresponding to the peripheral edge area of the frame, and having a bonding surface on which an adhesive member is provided. A portion of the first elastic member and a portion of the second elastic member are disposed on the frame to overlap each other, the bonding surface of the first elastic member has a first area overlapping the second elastic member, and a second area overlapping the frame at a position near a center of the first elastic member relative to the first area, and the adhesive member is divided between the first area and the second area.

### BACKGROUND OF THE INVENTION

1. Field of the Invention

The present invention relates to a display device including an elastic member between a display panel and a frame.

2. Description of the Related Art

A display device using a display panel such as a liquid crystal panel includes a frame, the display panel, and a light source device. The display panel has a display area for displaying an image, and a peripheral edge area around the display area. The frame having a frame shape and having an opening at the center is positioned in front of the display panel. An elastic member is disposed on the frame at a position corresponding to the peripheral edge area of the display panel. When the display device is assembled, the elastic member is fixedly held between the frame and the display panel.

The light source device is disposed in back of the display panel, and emits light to the display panel. The light source device includes a frame (panel holder), an optical sheet, a light source substrate, and a backlight housing. A plurality of light sources is disposed in the light source substrate, and the light source substrate is stored in the backlight housing having an opening on the front side. The optical sheet is disposed forward of the light source substrate, and stored in the backlight housing.

The frame having a frame shape and having an opening at the center is disposed in front of the optical sheet, and the optical sheet is fixedly held between the frame and the backlight housing. On the frame, the elastic member is disposed at a position corresponding to the peripheral edge area of the display panel. When the display device is assembled, the elastic member is fixedly held between the display panel and the frame.

The elastic member including a soft material reduces a stress locally applied to the display panel. Furthermore, the elastic member is deformed along ridges and grooves on the surface of the display panel and ridges and grooves on the surface of the frame, and adheres closely to the surfaces. Thus, the elastic member reduces a gap between the display panel and the frame, and inhibits entry of foreign substance such as dust between the display panel and the optical sheet.

Japanese Patent Application Laid-Open No. 2008-191607 discloses a liquid crystal display device having a configuration in which a display panel has a long side and a short side, and elastic members are disposed on the long side and the short side, one elastic member abutting on the other elastic member at a corner portion of the display panel, into a T-shaped arrangement. The T-shaped arrangement reduces a gap between the elastic members, and inhibits entry of foreign substance such as dust.

### SUMMARY OF THE INVENTION

A display device according to an embodiment of the present invention includes a display panel having a display area on which an image is displayed, and a peripheral edge area around the display area, a frame disposed in front or in back of the display panel, and a first elastic member and a second elastic member which are disposed at positions corresponding to the peripheral edge area of the frame, and each having a bonding surface on which an adhesive member is provided. A portion of the first elastic member and a portion of the second elastic member are disposed on the frame to overlap each other, the bonding surface of the first elastic member has a first area overlapping the second elastic member and a second area overlapping the frame at a position near a center of the first elastic member relative to the first area, and the adhesive member, provided on the bonding surface of the first elastic member, is divided between the first area and the second area.

Further features of the present invention will become apparent from the following description of exemplary embodiments (with reference to the attached drawings).

### BRIEF DESCRIPTION OF THE DRAWINGS

FIG. 1 is an overall exploded perspective view of a liquid crystal display device 1 according to a first example.

FIG. 2A is an enlarged view illustrating a corner portion of a frame 30 after a process of attachment of elastic members according to the first example.

FIG. 2B is a cross-sectional view of the corner portion of the frame 30 after the process of attachment of the elastic members according to the first example, taken along a line C-C of FIG. 2A.

FIG. 2C is a cross-sectional view of the corner portion of the frame 30 after the process of attachment of the elastic members according to the first example, taken along a line D-D of FIG. 2A.

FIG. 3A is a cross-sectional view illustrating a state of elastic members in the vicinity of a first area R1, where an elastic member 31 is pressed under a load against an elastic member 32, in a process of attachment of the elastic member 31 according to the first example.

FIG. 3B is a cross-sectional view illustrating a state of the elastic members in the vicinity of the first area R1, where the load is removed, in the process of attachment of the elastic member 31 according to the first example.

FIG. 4A is a first cross-sectional view illustrating a state of elastic members in the vicinity of a first area R1, where an adhesive member is not provided with a divided portion.

FIG. 4B is a second cross-sectional view illustrating a state of elastic members in the vicinity of a first area R1, where an adhesive member is not provided with a divided portion.

FIG. 5A is a front view of a dust entry path in the liquid crystal display device 1 according to the first example, viewed from a front side of the liquid crystal display device 1.

FIG. 5B is a cross-sectional view illustrating the dust entry path in the liquid crystal display device 1, taken along a line E-E of FIG. 5A.

FIG. 6 is a cross-sectional view illustrating a state of elastic members according to the first example, where an area in which an adhesive member 36 is not disposed is added between a first area R1 and a third area R3.

FIG. 7A is an enlarged view illustrating a corner portion of a frame 10 according to the first example.

FIG. 7B is a cross-sectional view of the corner portion of the frame 10 according to the first example, taken along a line F-F of FIG. 7A.

FIG. 7C is a cross-sectional view of the corner portion of the frame 10 according to the first example, taken along a line G-G of FIG. 7A.

FIG. 8A is a first front side view illustrating the whole of a frame 30 on which elastic members 31 and elastic members 32 are disposed.

FIG. 8B is a second front side view illustrating the whole of a frame 30 on which an elastic member 31 and an elastic member 32 are disposed.

FIG. 9A is an enlarged view illustrating a corner portion of a frame 30 after a process of attachment of elastic members according to a second example.

FIG. 9B is a cross-sectional view of the corner portion of the frame 30 after the process of attachment of the elastic members according to the second example, taken along a line C-C of FIG. 9A.

FIG. 9C is a cross-sectional view of the corner portion of the frame 30 after the process of attachment of the elastic members according to the second example, taken along a line D-D of FIG. 9A.

FIG. 10A is an enlarged view illustrating a portion A of a frame 30 after a process of attachment of elastic members according to a third example.

FIG. 10B is a cross-sectional view of the portion A of the frame 30 after the process of attachment of the elastic members according to the third example, taken along a line H-H of FIG. 10A.

FIG. 11A is a diagram illustrating a portion A of a frame 30 after a process of attachment of elastic members according to a fourth example.

FIG. 11B is a cross-sectional view of the portion A of the frame 30 after the process of attachment of the elastic members according to the fourth example, taken along a line I-I of FIG. 11A.

FIG. 11C is a cross-sectional view of the portion A of the frame 30 after the process of attachment of the elastic members according to the fourth example, taken along a line J-J of FIG. 11A.

### DESCRIPTION OF THE EMBODIMENTS

An embodiment of the present invention will be described below using the drawings. The technical scope of the present invention is determined by the scope of the appended claims and is not limited to the following exemplary embodiments. In addition, all the combinations of features described in the embodiments are not necessarily essential to the present invention. It should be understood that the contents described in the present specification and the drawings is illustrative only and is not intended to limit the present invention. Various modifications (including organic combinations of the embodiments) can be made based on the spirit of the present invention and are not excluded from the scope of the present invention without departing from the scope of the present invention. That is, the present invention includes all arrangements as combinations of the above-describe embodiments and their modifications.

### FIRST EXAMPLE

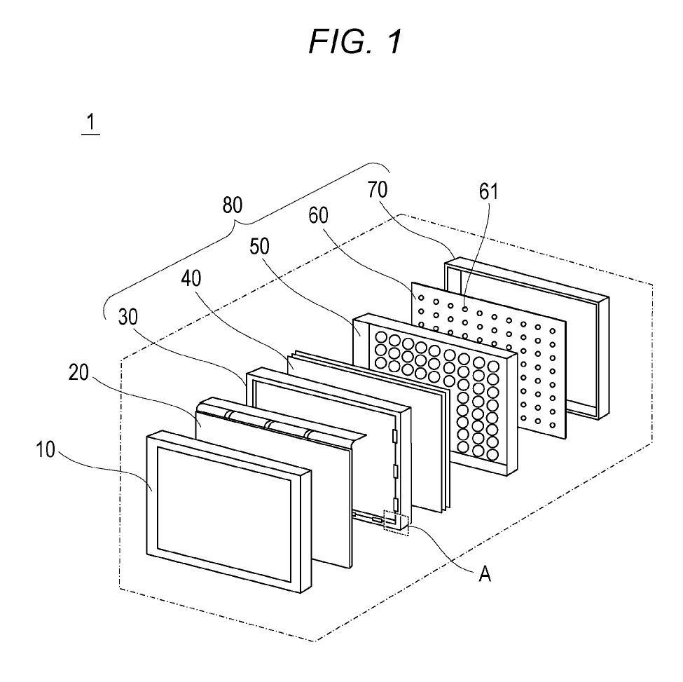

An example of the present invention will be described below with reference to the drawings. FIG. 1 is an overall exploded perspective view of a liquid crystal display device 1 according to a first example of the present invention.

A liquid crystal display device 1 includes a frame 10, a liquid crystal panel 20, and a light source device 80. The light source device 80 includes a frame 30, an optical sheet 40, a reflection sheet 50, a light source substrate 60, and a backlight housing 70. The liquid crystal panel 20 has a display area for displaying an image, and a peripheral edge area around the display area. The liquid crystal panel 20 is fixedly held between the frame 10 and the frame (panel holder) 30 of the light source device 80.

The light source device 80 is disposed in back of the liquid crystal panel 20, and emits light to the liquid crystal panel 20. A plurality of light sources 61 is disposed on the light source substrate 60. In the present example, each of the light sources 61 employs a light emitting diode (LED).

Note that the light source 61 can employ a light source other than the LED. For example, a cold cathode fluorescent lamp or an electro luminescence (EL) element may be employed. In addition, the light source 61 may be disposed not only on a part of the light source substrate 60 corresponding to a back surface of the display area of the liquid crystal panel but also at an end of the light source substrate 60.

The reflection sheet 50 is molded from a white polyethylene terephthalate (PET) material, has plurality of openings for exposing the plurality of light sources 61, and is disposed on the light source substrate 60. The reflection sheet 50 reflects light of the light sources 61, and inputs the light into the optical sheet 40.

The optical sheet 40 includes a plurality of optical members. In the present example, the optical sheet 40 includes a viewing angle improvement film, a brightness-enhancement film, and a brightness diffusion film. Each of the films includes an acrylic resin and a polyester substrate. The optical sheet 40 adjusts the characteristics of the light input into the optical sheet 40 from the light source substrate 60. The optical sheet 40 is fixedly held between the backlight housing 70 and the frame 30.

The backlight housing 70 is formed from a steel sheet into a frame shape. The optical sheet 40, the reflection sheet 50, and the light source substrate 60 are stored inside the backlight housing 70. Light is emitted from the light source device 80 to the display area of the liquid crystal panel 20, and an image is displayed

Note that, in the present example, description will be made of the liquid crystal display device using a transmissive liquid crystal panel as a display panel, but the display device is not limited to the transmissive liquid crystal display device. For example, the display device may be a reflective liquid crystal display device. Furthermore, the display device may be a MEMS shutter display using a micro electro mechanical system (MEMS) shutter instead of a liquid crystal element.

The frame 10 having a frame shape is disposed in front of the liquid crystal panel 20. The frame 10 includes a steel sheet having a thickness of 1 mm, divided along a peripheral edge area of the liquid crystal panel 20, and bent into an L-shape to cover side surfaces of the liquid crystal panel 20 and the light source device 80. The frame 10 and the backlight housing 70 are fixedly fastened with screws.

The frame 30 is molded from an acrylonitrile butadiene styrene (ABS) resin to be divided into four sides. The divided sides of the frame 30 are fastened to the backlight housing 70 with screws so that the four sides of the frame 30 are assembled into a frame shape. The frame assembled into the frame shape secures the liquid crystal panel 20 to maintain a certain space between the liquid crystal panel 20 and the optical sheet 40.

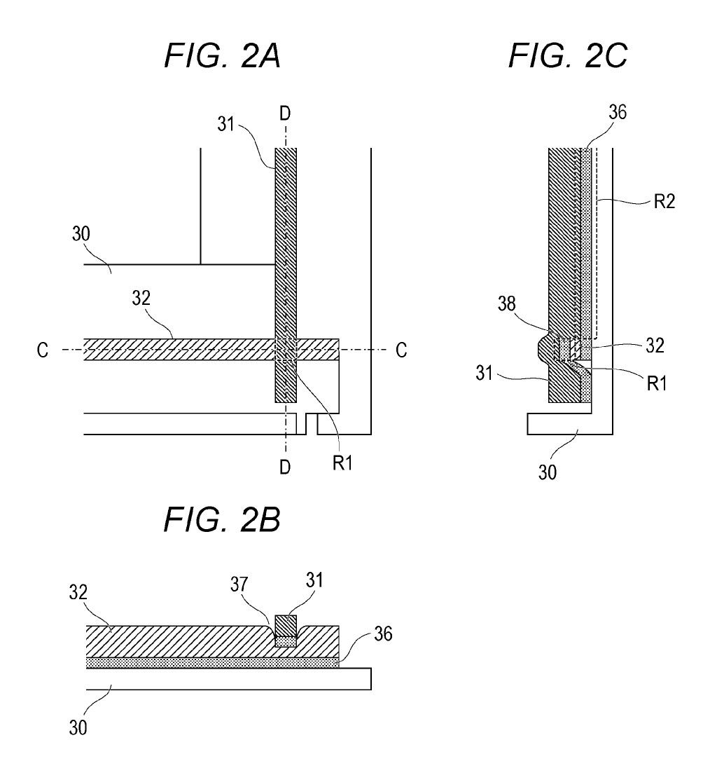

FIGS. 2A to 2C illustrate a corner portion of the frame 30 after a process of attachment of elastic members according to the present example. FIG. 2A is an enlarged view of a portion A of a frame 30 in FIG. 1, FIG. 2B is a cross-sectional view taken along a line C-C of FIG. 2A, and FIG. 2C is a cross-sectional view taken along a line D-D of FIG. 2A.

An elastic member 32 is disposed on a long side of the frame 30 corresponding to a long side of the peripheral edge area of the liquid crystal panel 20. Furthermore, an elastic member 31 is disposed on a short side of the frame 30 corresponding to a short side of the peripheral edge area of the liquid crystal panel 20. The elastic member 31 and the elastic member 32 are fixed on the frame 30 with an adhesive member 36. The elastic member 31 and the elastic member 32 are fixedly held between the liquid crystal panel 20 and the frame 30, when the liquid crystal display device 1 is assembled.

Each of the elastic members includes an elastic material having a semi-closed cell structure of ethylene propylene rubber. The elastic member has a compressive load at 80% compression of 0.15 (N/cm²), and a linear expansion coefficient of 230 to 240×10⁻⁶/° C., in physical property. Each elastic member has a bonding surface, and on the bonding surface, a double-sided adhesive tape is attached as the adhesive member 36. The double-sided adhesive tape is obtained by laminating an acrylic pressure sensitive adhesive on a film substrate.

Each elastic members is fixed to the frame 30 with the adhesive member 36. At this time, at the corner portion, an end portion of the elastic member 31 is disposed to cross and overlap an end portion of the elastic member 32. The area in which the elastic member 31 and the elastic member 32 overlap each other is defined as a first area R1. The overlapping between the elastic member 31 and the elastic member 32 can inhibit generation of a gap which is caused by a positional error in attachment of the elastic members or dimensional tolerance between the elastic members.

As illustrated in FIG. 2B, in the cross-section taken along the line C-C, the elastic member 32 is pressed into the elastic member 31, and the gap 37 having a triangular shape is generated in the vicinity of the first area R1 of the elastic member 32. In the present example, a cross-sectional area of the gap 37 of the elastic member was 0.01 m².

As illustrated in FIG. 2C, the bonding surface of the elastic member 31 has a second area R2 in which the elastic member 31 is bonded to the frame 30, on the center side of the elastic member 31 relative to the first area R1. The adhesive member 36 is separated between the first area R1 and the second area R2. A portion at which the adhesive member 36 is separated is defined as a divided portion 38 of the adhesive member 36. When the elastic member 31 is pressingly attached to the frame 30 and the elastic member 32, the elastic member 31 at the divided portion 38 can be extended.

Note that, in the present example, the order of attachment of the elastic members has been exemplified in which the elastic member 32 is attached first, and the elastic member 31 is attached next. However, the elastic member 32 may be attached after the elastic member 31 is attached. In this configuration, in the bonding surface of the elastic member 32, the adhesive member 36 is separated between the first area R1 overlapping the elastic member 31, and the second area R2 positioned on the frame 30 on the center side of the elastic member 32 relative to the first area R1.

Furthermore, the adhesive member 36 may be divided by being cut between the first area R1 and the second area R2 of the adhesive member 36 disposed over the first area R1 and the second area R2. At this time, at a portion where the adhesive member 36 is divided, the elastic member may be partially cut. When the elastic member is partially cut, the elastic member is improved in expansion and contraction properties, and has better adhesion.

Furthermore, the adhesive member 36 can be divided not by cutting between the first area R1 and the second area R2 of the adhesive member 36, but by disposing two adhesive members 36 in the first area R1 and the second area R2, respectively. Furthermore, a material having a ductility lower than that of the elastic member may be used as the adhesive member 36, to divide the adhesive member 36 in the vicinity of the first area R1, when the elastic member 31 is disposed to overlap the elastic member 32.

Note that, in the present example, the adhesive member 36 having a tape shape in which the pressure sensitive adhesive is laminated on the film substrate has been described, but the adhesive member 36 is not limited to this example. For example, the pressure sensitive adhesive may be applied to an elastic member to obtain the adhesive member 36.

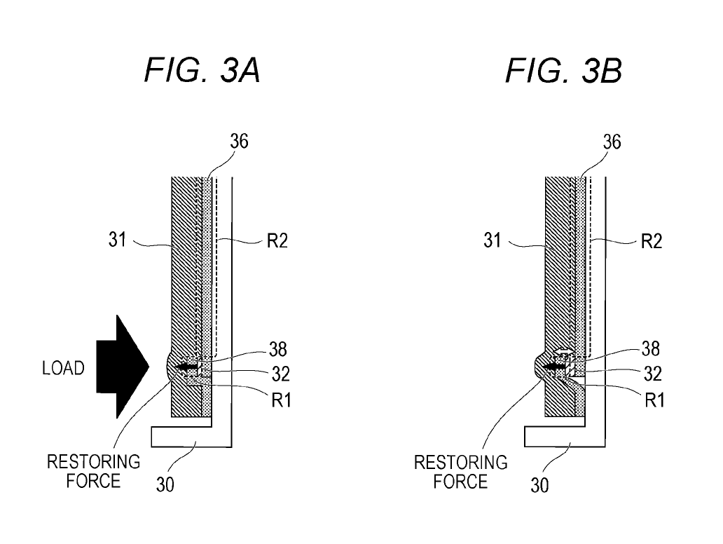

FIGS. 3A and 3B are cross-sectional views each illustrating a state of the elastic members in the vicinity of the first area R1, in the process of attachment of the elastic member 31. FIGS. 3A and 3B each illustrate a cross-sectional view of the short side of the frame 30 corresponding to the cross-section taken along the line D-D of FIG. 2A. FIG. 3A is a cross-sectional view of the vicinity of the first area R1, where the elastic member 31 is pressed under a load against the elastic member 32. Furthermore, FIG. 3B is a cross-sectional view of the vicinity of the first area R1, where the load is removed.

As illustrated in FIG. 3A, the elastic member 31 and the elastic member 32 in the vicinity of the first area R1 are compressed under the load toward the frame 30. As indicated by a black arrow in FIG. 3A, the elastic member 31 and the elastic member 32 each have an elastic force to generate a restoring force for restoration. However, the applied load is sufficiently strong relative to the restoring force, and the elastic member 31 and the elastic member 32 are compressed to adhere closely to each other.

As illustrated in FIG. 3B, when the load is removed in the attachment process, only the restoring force is applied to the first area R1 in a direction in which the shape thereof is restored. By the restoring force, the elastic member 32 in the first area R1 is expanded to restore the thickness thereof. By the expansion of the elastic member 32, the elastic member 31 in the first area R1 is raised toward the liquid crystal panel 20.

At this time, in a portion in which the adhesive member 36 is divided, the elastic member 31 is extended in a direction indicated by an arrow in FIG. 3B. Thus, a force applied to the adhesive member 36 bonding the elastic member 31 and the frame 30 is reduced in the vicinity of the first area R1, thereby inhibiting separation of the adhesive member 36 in the second area R2.

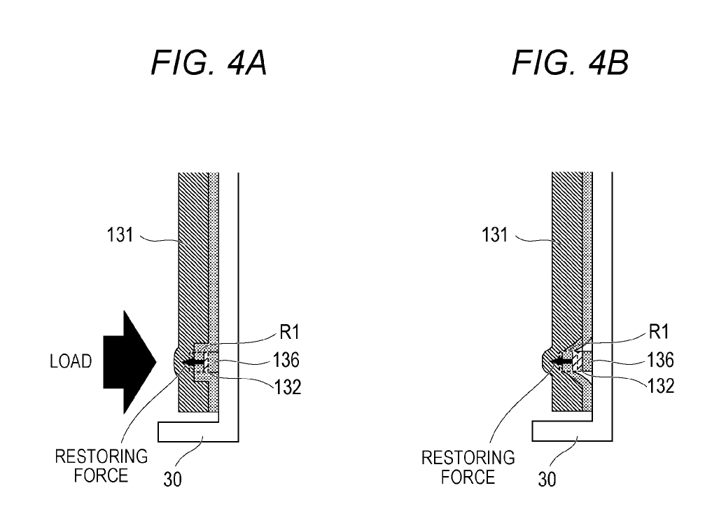

For comparison with the present example, FIGS. 4A and 4B are provided. FIGS. 4A and 4B are cross-sectional views each illustrating a state of elastic members in the vicinity of the first area R1, where a continuous adhesive member 136 is disposed on a bonding surface of an elastic member. Component elements being the same as those of FIG. 2 are denoted by the same reference signs, and detailed description thereof will not be repeated. Similar to FIGS. 3A and 3B, FIGS. 4A and 4B illustrate cross-sectional views corresponding to the cross-section take along the line D-D of FIG. 2A. FIG. 4A is a cross-sectional view of the vicinity of the first area R1, where an elastic member 131 is pressed under a load against an elastic member 132. Furthermore, FIG. 4B is a cross-sectional view of the vicinity of the first area R1, where the load is removed.

As illustrated in FIG. 4A, while the load is applied, the elastic member 131 and the elastic member 132 adhere closely to each other in the vicinity of the first area R1, similar to FIG. 3A. As illustrated in FIG. 4B, when the load is removed in the attachment process, the elastic member 132 in the first area R1 has a restoring force to raise the elastic member 131.

At this time, the elastic member 131 intents to deform with deformation of the elastic member 132. In contrast, since the adhesive member 136 has low expansion and contraction properties, the adhesive member 136 in the first area R1 draws the adhesive member 136 in the vicinity of the first area R1. A force drawing the adhesive member 136 in the first area R1 acts in a direction separating the adhesive member 136 positioned between the elastic member 131 in the vicinity of the first area R1 and the frame 30. Thus, the adhesive member 136 positioned between the elastic member 131 and the frame 30 may be separated, and a gap positioned between the elastic member 131 and the frame 30 may be enlarged.

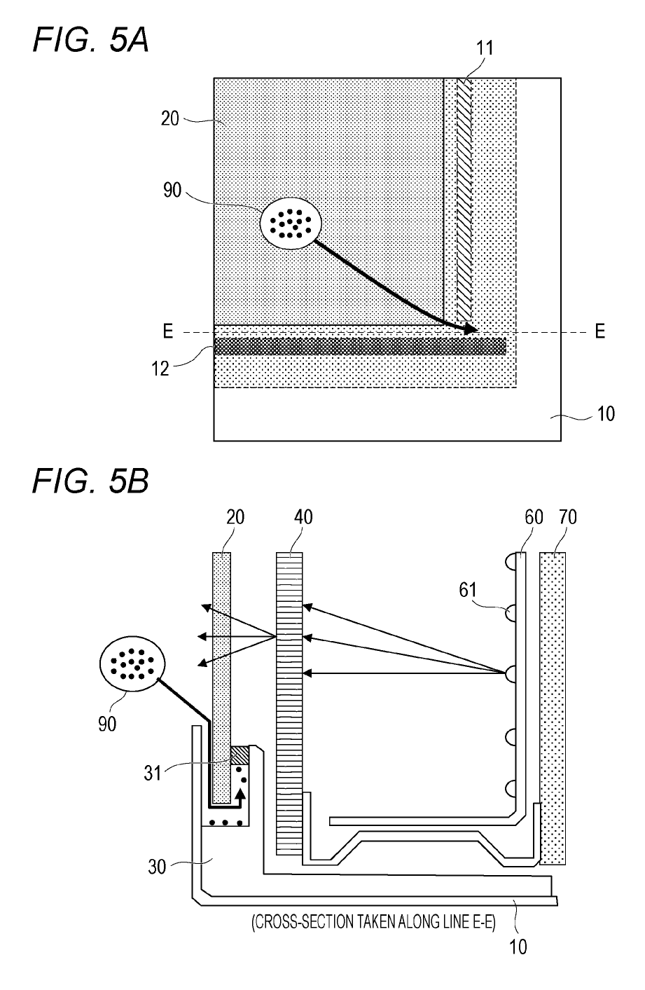

FIGS. 5A and 5B each illustrate a dust entry path in the liquid crystal display device 1 according to the present example. FIG. 5A is a front view of the liquid crystal display device 1, viewed from the front side thereof through the frame 10 and the liquid crystal panel 20. FIG. 5B is a cross-sectional view taken along a ling E-E of FIG. 5A.

As illustrated in FIG. 5A, an elastic member 11 is disposed on a short side of the frame 10 corresponding to the short side of the peripheral edge area of the liquid crystal panel 20. Furthermore, an elastic member 12 is disposed on a long side of the frame 10 corresponding to the long side of the peripheral edge area of the liquid crystal panel 20.

In the present example, the elastic member 11 and the elastic member 12 are disposed to abut on each other into T-shape at a corner portion, but a gap is generated at the corner portion due to a positional error in attachment. The elastic member 11 and the elastic member 12 are positioned to be held between the frame 10 and the liquid crystal panel 20.

The dust 90 enters the liquid crystal display device 1 from the gap between the elastic member 11 and the elastic member 12. As illustrated in FIG. 5B, the dust 90 entering from outside moves behind an end of the liquid crystal panel 20, and enters a space between the frame 10 and the frame 30.

Although the dust 90 enters up to the elastic member 31 attached on a back surface of the liquid crystal panel 20, the liquid crystal panel 20 and the frame 30 adhere closely to each other in the second area R2 as illustrated in FIG. 2C, and the dust 90 cannot enter the display area. Furthermore, as illustrated in FIG. 2C, also between the first area R1 and the second area R2, the elastic member 31 and the elastic member 32 adhere closely to each other, and the dust 90 cannot enter the display area.

The elastic member 31 and the elastic member 32 are positioned outside the display area of the liquid crystal panel 20, so that most of the dust 90 accumulated in the vicinity of the elastic members stays outside the display area. Thus, the dust 90 entering between the elastic member 11 and the elastic member 12 on a side of the frame 10 does not influence image quality.

Note that although description has been made of a structure of the corner portion of one corner selected from the four corners of the frame 30 assembled into a frame shape, corner joint portions of the remaining three corners have a similar structure. Furthermore, although the configuration of the frame 30 divided into four parts has been exemplified above, the frame 30 may be integrally formed. In that configuration, as long as the elastic member 31 and the elastic member 32 are attached to overlap each other at a corner portion, as described above, similar effects can be obtained.

Furthermore, in the present example, although the elastic member 31 and the elastic member 32 have been exemplified which are disposed to cross each other, the end portion of the elastic member 31 and the end portion of the elastic member 32 may be disposed to overlap each other thereof. In this configuration, similar effects can be obtained, when the bonding surface of the elastic member 31 has a first area overlapping the elastic member 32, and a second area bonding the elastic member 31 and the frame 30 together, and the adhesive member 36 is divided between the first area and the second area.

In the present example, the adhesive member 36 has been exemplified which is divided between the first area R1 and the second area R2 of the bonding surface, the second area R2 being positioned on the center side relative to the first area R1. In addition, a portion in which the adhesive member 36 is divided may be added between the first area R1 and a third area R3 positioned on a side opposite to the center relative to the first area R1.

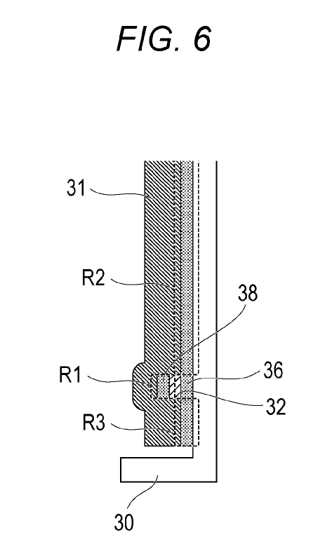

In addition to the divided portion 38 illustrated in FIGS. 2A to 2C, FIG. 6 illustrates a cross-sectional view of a divided portion 38, taken along the line D-D of FIG. 2A, the divided portion 38 being added between the first area R1 and the third area R3, the adhesive member 36 being divided at the divided portion 38.

The divided portion 38 of the adhesive member 36 added between the first area R1 and the third area R3 facilitates extension of the elastic member 31 at a plurality of divided portions 38 on both sides of the first area R1. Accordingly, in addition to the second area R2, the separation of the adhesive member 36 between the elastic member 31 and the frame 30 is also inhibited in the third area R3. Thus, adhesion between the elastic member 31 and the frame 30 is further improved.

Furthermore, a divided portion may be added around the divided portion 38 illustrated in FIG. 2C. For example, in the vicinity of the divided portion 38 illustrated in FIG. 2C, a plurality of divided portions 38 can be previously provided on a side of the first area R1 and a side of the second area R2, respectively. With such a configuration, even if positional displacement occurs while the elastic members 31 and 32 are disposed on the frame 30, at least any of the plurality of divided portions 38 previously provided is disposed between the first area R1 and the second area R2. Thus, the adhesion can be increased against the positional displacement of the elastic members 31 and 32.

According to the present example, in the attachment process, adhesion between the elastic members are improved, and inhibition in the separation of the adhesive member 36 in the vicinity of the first area R1 can inhibit enlargement of the gap between the elastic members due to positional displacement or expansion and contraction of the elastic members. Thus, the dust can be inhibited from entering from outside between the display area of the liquid crystal panel 20 and the optical sheet 40, thereby inhibiting deterioration in image quality, such as reduction in brightness.

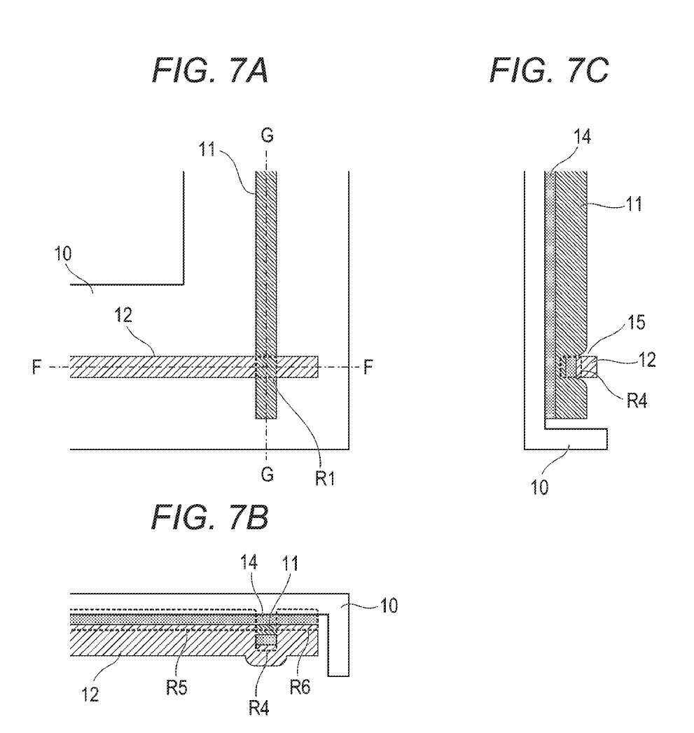

Note that the elastic member 11 and the elastic member 12 disposed on the frame 10 can have a configuration similar to that of the present example. FIGS. 7A to 7C are enlarged views each illustrating the vicinity of the frame 10 opposite to the portion A of the frame 30. FIG. 7A is an enlarged view of a lower right corner portion of the frame 10, illustrating disposition of the elastic member 11 and the elastic member 12 through the frame 10. FIG. 7B is a cross-sectional view taken along a line F-F of FIG. 7A. FIG. 7C is a cross-sectional view taken along a line G-G of FIG. 7A.

As illustrated in FIG. 7A, after the elastic member 11 is disposed on the frame 10, the elastic member is disposed to overlap the elastic member 11 at the corner portion. Each of the elastic members is bonded to the frame 10 with an adhesive member 14. Furthermore, as illustrated in FIG. 7C, a gap 15 is positioned in the vicinity of a first area R4 in which the elastic member 12 overlaps the elastic member 11.

The elastic member 12 has a bonding surface, and the bonding surface has the first area R4 in which the elastic member 11 and the elastic member 12 overlap each other. Furthermore, the bonding surface of the elastic member 12 has a second area R5 bonded to the frame 10 on the center side of the elastic member 12 relative to the first area R4, and a third area R6 bonded to the frame 10 on a side opposite to the center of the elastic member 12 relative to the first area R4.

As illustrated in FIG. 7B, in the bonding surface of the elastic member 12, the adhesive member 14 is divided between the first area R4 and the second area R5, and the first area R4 and the third area R6. At this time, similar to an example of the frame 30 illustrated in FIG. 6, in the vicinity of the first area R4, adhesion between the elastic member 11 and the elastic member 12 is improved. Furthermore, even if a load during attachment is removed, separation of the adhesive member 14 bonding the second area R5 and the third area R6 to the frame 10 is inhibited.

As described above, the overlapping between the elastic member 11 and the elastic member 12 can inhibit a gap from being enlarged due to positional error in attachment of the elastic member 11 and the elastic member 12 or dimensional tolerance between the elastic member 11 and the elastic member 12. Furthermore, the adhesive member 14 divided in the vicinity of the first area R4 facilitates extension of the elastic member 12. Thus, separation of the adhesive member 14 is inhibited in the vicinity of the first area R4, and enlargement of the gap is suppressed. Thus, the dust 90 can be inhibited from entering the liquid crystal display device 1 from outside, thereby inhibiting deterioration in image quality, such as reduction in brightness.

In the example described above, a portion in which the adhesive member 14 is divided is preferably provided at least between the first area R4 and the second area R5. Furthermore, a divided portion may be added around the divided portion illustrated in FIG. 7B. For example, in the vicinity of the divided portion illustrated in FIG. 7B, a plurality of divided portions can be previously provided. With such a configuration, even if positional displacement occurs while the elastic members 11 and 12 are disposed on the frame 10, at least any of the plurality of divided portions previously provided is disposed between the first area R4 and the second area R5, or the first area R4 and the third area R6. Thus, the separation of the adhesive member 14 due to positional displacement of the elastic members 11 and 12 can be also inhibited.

Note that the elastic member 31 and the elastic member 32 mounted on the frame 30 may be disposed into a T-shape at the corner portion, but also can be arranged as described in the present example. In other words, it could be said that a plurality of elastic members disposed respectively on the frame 10 and the frame 30 can have the adhesive member divided between the first area and the second area.

In this configuration, a slight amount of dust 90 capable of passing through the gap 15 on the side of the frame 10 enters a space located among the frame 10, the liquid crystal panel 20, and the frame 30. However, as illustrated in FIG. 2C, the gap between the elastic member 31 and the elastic member 32 mounted on the frame 30 is small, and thus, the slight amount of dust 90 is further inhibited from entering between the liquid crystal panel 20 and the optical sheet 40. Thus, entry of the dust 90 is inhibited, thereby further increasing the effect of inhibiting deterioration in image quality, such as reduction in brightness.

Furthermore, in this configuration, the first area R4 of the elastic member on the side of the frame 10 and the first area R1 of the elastic member on a side of the frame 30 may be located at different positions. The dust 90 intends to enter between the liquid crystal panel 20 and the optical sheet 40 through a gap in the vicinity of the first area R4 on the side of the frame 10 and a gap in the vicinity of the first area R1 on the side of the frame 30. A distance between the first area R1 on the side of the frame 30 and the first area R4 on the side of the frame 10 is increased to have a long migration path of the dust 90 to reach the display area. The dust 90 is for example adsorbed on another member in the middle of the long migration path, and the amount of dust 90 reaching between the display area of the liquid crystal panel 20 and the optical sheet 40 is further reduced.

In the present example, a gap between the liquid crystal panel 20 and the frame 10 is 1.0 mm, and a gap between the liquid crystal panel 20 and the frame 30 is 2.0 mm. The elastic member 11 and the elastic member 12 have a thickness of 1.5 mm so that the elastic members are brought into contact with the liquid crystal panel 20. Similarly, the elastic member 31 and the elastic member 32 have a thickness of 3.0 mm. The elastic members preferably fill a gap between the frame 10 or 30 and the liquid crystal panel 20, and may have a non-uniform thickness or may have a non-square columnar shape.

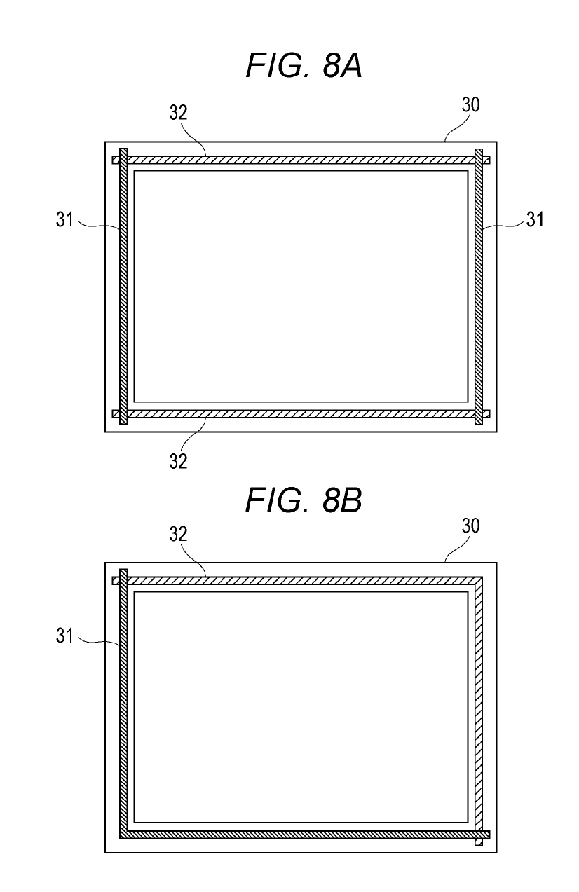

FIGS. 8A and 8B are front side views each illustrating the whole of the frame 30 on which the elastic members 31 and 32 are disposed. As illustrated in FIG. 8A, the frame 30 has a rectangular frame shape corresponding to the peripheral edge area of the liquid crystal panel 20. When linear elastic members are disposed at positions corresponding to the long sides and the short sides of the frame 30, the elastic members may overlap each other at four corners, as described in the present example. Furthermore, as illustrated in FIG. 8B, when a plurality of L-shaped elastic members is disposed to be positioned over the long sides and the short sides, the elastic members may overlap each other at two corners opposite to each other across the display area, as described in the present example. The elastic members can be also disposed on the frame 10, similarly to the above-mentioned configuration.

### SECOND EXAMPLE

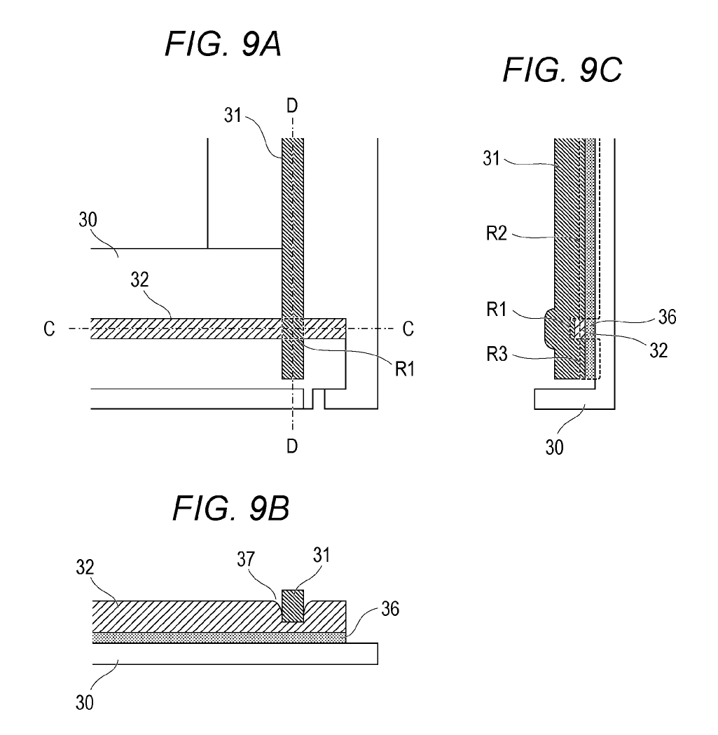

FIGS. 9A to 9C each illustrate the corner portion of the frame 30 after the process of attachment of the elastic members according to a second example. FIG. 9A is an enlarged view of the portion A of the frame 30 of FIG. 1. FIG. 9B is a cross-sectional view taken along a line C-C of FIG. 9A, and FIG. 9C is a cross-sectional view taken along a line D-D of FIG. 9A. The same configurations as those of the first example are denoted by the same reference signs, and description thereof will be omitted.

In the present example, the adhesive member 36 of the elastic member 31 is not disposed in the first area R1. In other words, it could be said that the adhesive member 36 is divided in a space from a part between the first area R1 and the second area R2 to a part between the first area R1 and the third area R3.

According to the present example, overlapping between the elastic member 31 and the elastic member 32 can inhibit generation of a gap which is caused by a positional error in attachment of the elastic members or dimensional tolerance between the elastic members.

When the elastic member 31 is attached to the elastic member 32 and the frame 30, the elastic member 31 is fixed only on the frame 30 with the adhesive member 36. The elastic member 31 is not fixed on the elastic member 32 in the first area R1, and thus, the elastic member 31 in the vicinity of the first area R1 can be readily expanded and contracted.

Thus, adhesion between the elastic member 31 and the elastic member 32 is improved, and the gap between the elastic member 31 and the elastic member 32 can be reduced in size. Thus, the dust 90 can be inhibited from entering from outside between the display area of the liquid crystal panel 20 and the optical sheet 40, thereby inhibiting deterioration in image quality, such as reduction in brightness.

In the present example, the elastic members disposed on the frame 30 have been exemplified above, but the elastic member 11 and the elastic member 12 disposed on the frame 10 can have a configuration similar to that of the present example.

### THIRD EXAMPLE

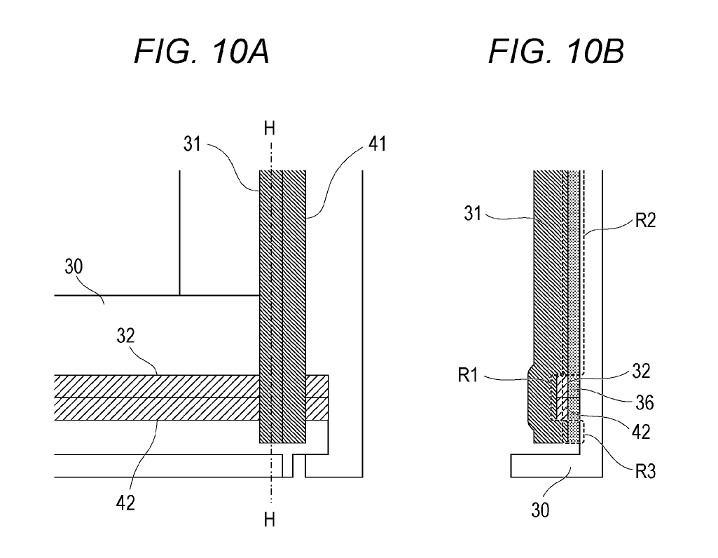

FIGS. 10A and 10B each illustrate the portion A of the frame 30 after the process of attachment of the elastic members according to a third example. FIG. 10A is an enlarged view of the portion A of the frame 30 in FIG. 1. FIG. 10B is a cross-sectional view taken along a line H-H of FIG. 10A. The same configurations as those of the first example are denoted by the same reference signs, and description thereof will be omitted.

As illustrated in FIG. 10A, a second elastic member 42 is adjacently disposed on an outer side of the elastic member 32 disposed on the frame 30. Furthermore, a second elastic member 41 is adjacently disposed on an outer side of the elastic member 31. At this time, a portion of the elastic member 31 and a portion of the second elastic member 41 are disposed by overlapping a portion of the elastic member 32 and a portion of the second elastic member 42.

As illustrated in FIG. 10B, the adhesive members 36 of the elastic member 31 and the second elastic member are not provided in the first area R1 in which the elastic member 31 and the second elastic member 41 are overlappingly disposed on the elastic member 32 and the second elastic member 42. In other words, it could be also said that the adhesive member 36 is divided the second area R2 and between the first area R1 and the third area R3 in the bonding surfaces of the elastic member 31 and the second elastic member 41.

Thus, when the elastic member 31 and the second elastic member 41 are attached to the frame 30, the elastic member 31 and the second elastic member 41 adhere well to the frame 30, and the elastic member 32 and the second elastic member 42. Furthermore, between the frame 30 and the bonding surfaces of the elastic member 31 and the second elastic member 41, a force acting in a direction separating the adhesive member 36 is reduced

According to the present example, the overlapping between the elastic members can inhibit the gap from being enlarged due to a positional error in attachment of the elastic members or dimensional tolerance between the elastic members. Furthermore, the elastic member 31 and the second elastic member 41 are well extended in the vicinity of the first area R1, thereby inhibiting the separation of the adhesive member 36 between the frame 30 and the elastic member 31 and between the frame 30 and the second elastic member 41. Thus, enlargement of the gap can be suppressed between the elastic members.

Furthermore, even if adhesiveness of the adhesive member 36 is deteriorated due to deterioration over time or the like, and the adhesive member 36 is partially separated in the vicinity of the first area R1, attachment of the plurality of elastic members can suppress the enlargement of the gap. Thus, the dust can be inhibited from entering between the display area of the liquid crystal panel 20 and the optical sheet 40.

Note that the adhesive member 36 is preferably divided at least at one portion between the first area R1 and the second area R2, similar to the first example.

### FOURTH EXAMPLE

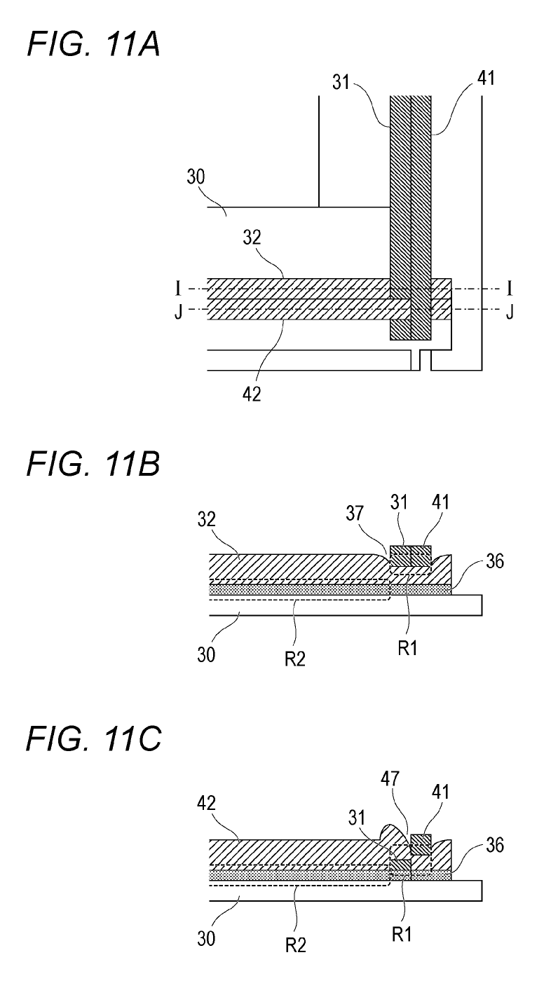

FIGS. 11A to 11C each illustrate the portion A of the frame 30 after the process of attachment of the elastic members according to a fourth example. FIG. 11A is an enlarged view of the portion A of the frame 30 of FIG. 1. FIG. 11B is a cross-sectional view taken along a line I-I of FIG. 11A. FIG. 11C is a cross-sectional view taken along a line J-J of FIG. 11A. The same configurations as those of the first example are denoted by the same reference signs, and description thereof will be omitted.

As illustrated in FIG. 11A, the second elastic member 42 is adjacently disposed on the outer side of the elastic member 32 disposed on the frame 30. Furthermore, the second elastic member 41 is adjacently disposed on the outer side of the elastic member 31. The elastic members each have the adhesive member 36 on a lower surface attached to the frame 30.

In the present example, firstly, the elastic member 32 is disposed on the frame 30. Then, a portion of the elastic member 31 is attached to overlap a portion of the elastic member 32. Then, a portion of the second elastic member 42 is attached to overlap a portion of the elastic member 31. Lastly, a portion of the second elastic member 41 is attached to overlap a portion of the elastic member 32 and a portion of the second elastic member 42. In other words, it could be said that the second elastic member 42 is disposed to vertically alternate the consecutively overlapping elastic members.

As illustrated in FIGS. 11B and 11C, the adhesive members 36 of the elastic members positioned on a side of the liquid crystal panel 20 are not disposed in the first area R1 in which the elastic members overlap each other. As illustrated in FIG. 11B, the elastic member 32 is pressed by the elastic member 31 and the second elastic member 41. In the elastic member 32, the gap 37 is generated in the vicinity of the first area R1. Furthermore, as illustrated in FIG. 11C, the second elastic member 42 is disposed over the elastic member 31 and pressed by the second elastic member 41. At this time, a gap 47 is generated in the second elastic member 42 in the vicinity of an area in which the second elastic member 42 is pressed by the second elastic member 41.

According to the present example, overlapping the elastic members can inhibit generation of the gap which is caused by a positional error in attachment of the elastic members or dimensional tolerance between the elastic members.

Furthermore, the adhesive members 36 of the elastic members positioned on the side of the liquid crystal panel 20 are not disposed in the first area R1 of the elastic member 31 and the second elastic member 32. Thus, adhesion between the elastic member 32, and the elastic member 31 and the second elastic member 41 is improved, the gaps in the vicinity of the first area R1 are reduced in size, and the entry of the dust can be inhibited.

Furthermore, the gap 37 and the gap 47 are displaced in position, relative to an axis directed from the peripheral edge area toward the display area. Thus, the dust intending to enter the display area from the gap 47 collides with the elastic member 32, and the dust is unlikely to enter the display area.

In the present example, the elastic members have been described repeatedly in order as described above, but the overlapping elastic members can be achieved in a reverse order. Furthermore, the adhesive member 36 is preferably divided at least at one portion between the first area and the second area, similarly to the first example, and may be divided at a plurality of portions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-054062, filed Mar. 17, 2015, which is hereby incorporated by reference herein in its entirety.

What is claimed is:

1. A display device comprising:
a display panel having a display area on which an image is displayed, and a peripheral edge area around the display area;
a frame disposed in front or in back of the display panel; and
a first elastic member and a second elastic member which are disposed at positions corresponding to the peripheral edge area of the frame, and each having a bonding surface on which an adhesive member is provided, wherein
a portion of the first elastic member and a portion of the second elastic member are disposed on the frame to overlap each other,
the bonding surface of the first elastic member has a first area overlapping the second elastic member and a second area overlapping the frame at a position near a center of the first elastic member relative to the first area, and
the adhesive member, provided on the bonding surface of the first elastic member, is divided between the first area and the second area.

2. The display device according to claim 1, wherein the adhesive member is divided at a plurality of portions between the first area and the second area.

3. The display device according to claim 1, wherein the first elastic member and the second elastic member are disposed to cross each other.

4. The display device according to claim 3, wherein
the bonding surface of the first elastic member has a third area bonded on the frame at a position opposite to the center of the first elastic member relative to the first area, and
the adhesive member provided on the bonding surface of the first elastic member is divided between the first area and the third area.

5. The display device according to claim 4, wherein the adhesive member provided on the bonding surface of the first elastic member is not disposed in the first area.

6. The display device according to claim 1, further comprising a third elastic member, which is disposed adjacent to the first elastic member, having a bonding surface on which the adhesive member is provided, wherein
a portion of the third elastic member is disposed on the frame to overlap a portion of the second elastic member,
the bonding surface of the third elastic member has a third area overlapping the second elastic member, and a fourth area overlapping the frame at a position near a center of the third elastic member relative to the third area, and
the adhesive member, provided on the bonding surface of the third elastic member, is divided between the third area and the fourth area.

7. The display device according to claim 1, further comprising a third elastic member disposed adjacent to the first elastic member, wherein
a portion of the second elastic member is disposed on the frame to overlap a portion of the third elastic member,
the bonding surface of the second elastic member has a third area overlapping a third elastic member, and a fourth area overlapping the frame at a position near a center of the second elastic member relative to the third area, and
the adhesive member, provided on the bonding surface of the second elastic member, is divided between the third area and the fourth area.

8. The display device according to claim 1, further comprising a first frame disposed in front of the display panel, and a second frame disposed in back of the display panel,
the first frame and the second frame each being configured to dispose the first elastic member and the second elastic member disposed to overlap the first elastic member.

9. The display device according to claim 1, wherein the bonding surface has a cut in a portion where the adhesive member is divided.

10. The display device according to claim 1, wherein the frame is formed into a rectangular frame shape corresponding to the peripheral edge area, and
the first elastic member and the second elastic member have a linear shape corresponding to sides of the frame.

11. The display device according to claim 1, wherein the frame is formed into a rectangular frame shape corresponding to the peripheral edge area, and
the first elastic member and the second elastic member have an L-shape corresponding to a long side and a short side of the frame.
